(19) United States
(12) Patent Application Publication
(10) Pub. No.: US 2026/0033294 A1
(43) Pub. Date: Jan. 29, 2026

(54) SUBSTRATE PROCESSING APPARATUS AND CONTROL METHOD OF SUBSTRATE PROCESSING APPARATUS

(71) Applicant: SAMSUNG ELECTRONICS CO., LTD., Suwon-si (KR)

(72) Inventors: Jisoo OH, Suwon-si (KR); KI-IL KIM, Suwon-si (KR); SOOKYUNG KIM, Suwon-si (KR); JUNGHYUN KIM, Suwon-si (KR); CHANGBEA PARK, Suwon-si (KR); KYUNGYUB JEON, Suwon-si (KR)

(73) Assignee: SAMSUNG ELECTRONICS CO., LTD., Suwon-si (KR)

(21) Appl. No.: 18/987,641

(22) Filed: Dec. 19, 2024

(30) Foreign Application Priority Data
Jul. 24, 2024 (KR) 10-2024-0098008

(51) Int. Cl. H01L 21/66; H01J 37/32

(52) U.S. Cl. CPC H01L 22/20; H01J 37/32568; H01J 37/32816; H01J 2237/1825; H01J 2237/186; H01J 2237/3343

(57) ABSTRACT

A substrate processing apparatus includes a chamber, a stage in the chamber and configured to accommodate a substrate, a vacuum pump connected to the chamber and configured to provide negative pressure to the chamber, and a controller, where the vacuum pump includes a pipe assembly connected to the chamber, the pipe assembly including a first pipe, at least one second pipe, a common pipe connected to the first pipe and the at least one second pipe, a first valve provided on the first pipe, and at least one second valve provided on the at least one second pipe, an intake port connected to the pipe assembly, and a pump connected to the intake port and configured to provide negative pressure.

### CROSS-REFERENCE TO RELATED APPLICATION

This application is based on and claims priority to Korean Patent Application No. 10-2024-0098008, filed on Jul. 24, 2024, in the Korean Intellectual Property Office, the disclosure of which incorporated by reference herein in its entirety.

### BACKGROUND

Example embodiments of the disclosure relate to a substrate processing apparatus and a control method of the substrate processing apparatus.

A semiconductor device may be manufactured through various processes. For example, the semiconductor device may be manufactured through the process of photolithography, etching, deposition, etc. performed on a wafer. In these processes, various fluids may be used. For example, plasma may be used in the etching and/or deposition processes.

In the process that uses plasma, etching may be performed in a high vacuum chamber to ensure the quality of the semiconductor device. Therefore, vacuum pumps such as turbo pumps may be used to form a high vacuum state in the chamber. During the semiconductor process, a flow of fluid suctioned into the vacuum pump may affect the process uniformity.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a substrate processing apparatus capable of improving process uniformity, and a control method thereof.

According to an aspect of an example embodiment, a substrate processing apparatus may include a chamber, a stage in the chamber and configured to accommodate a substrate, a vacuum pump connected to the chamber and configured to provide negative pressure to the chamber, and a controller, where the vacuum pump includes a pipe assembly connected to the chamber, the pipe assembly including a first pipe, at least one second pipe, a common pipe connected to the first pipe and the at least one second pipe, a first valve provided on the first pipe, and at least one second valve provided on the at least one second pipe, an intake port connected to the pipe assembly, and a pump connected to the intake port and configured to provide negative pressure, where a first end of the first pipe and a first end of the at least one second pipe are connected to the chamber, a second end of the first pipe and a second end of the at least one second pipe are connected to the intake port through the common pipe, and the controller is configured to individually control opening and closing of the first valve and opening and closing of the at least one second valve.

According to an aspect of an example embodiment, a substrate processing apparatus may include a chamber, a stage in the chamber and configured to accommodate a substrate, an upper electrode in the chamber and configured to provide plasma on the stage, a vacuum pump connected to the chamber and configured to provide negative pressure to the chamber, and a controller, where the vacuum pump includes a pipe assembly connected to the chamber, the pipe assembly including a first pipe, a plurality of second pipes, a common pipe connected to the first pipe and the plurality of second pipes, a first valve provided on the first pipe, a plurality of second valves respectively provided on the plurality of second pipes, and a body surrounding the first pipe and the plurality of second pipes, an intake port connected to the pipe assembly, and a pump connected to the intake port and configured to provide negative pressure, where the body includes a center region and a second region around the center region, and a first end of the first pipe is provided on the center region of the body, and first ends of each of the plurality of second pipes are provided on the second region of the body.

According to an aspect of an example embodiment, a control method of a substrate processing apparatus may include receiving uniformity data of a substrate, determining a valve open/close value based on the received uniformity data and valve data, and adjusting a degree of opening and closing of a first valve and a plurality of second valves based on the determined valve open/close value, where a first end of the first valve is provided in a central region of a pipe assembly, and first ends of each of the plurality of second valves are provided around the first valve.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing apparatus according to one or more embodiments;

FIG. 2 is a diagram illustrating a vacuum pump according to one or more embodiments;

FIG. 3 is a plan view illustrating a pipe assembly of a vacuum pump according to one or more embodiments;

FIG. 4 is a diagram illustrating a valve of a vacuum pump according to one or more embodiments;

FIG. 5 is a diagram illustrating a substrate processing apparatus according to one or more embodiments;

FIGS. 6A and 6B are diagrams illustrating a substrate processing apparatus according to one or more embodiments;

FIG. 7 is a diagram illustrating a substrate processing apparatus according to one or more embodiments;

FIGS. 8 and 9 are diagrams illustrating a control method of a substrate processing apparatus according to one or more embodiments;

FIGS. 10 and 11 are diagrams illustrating a control method of a substrate processing apparatus according to one or more embodiments; and

FIG. 12 is a flowchart illustrating a control method of a substrate processing apparatus according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Hereinafter, a substrate processing apparatus and a control method thereof according to one or more embodiments of the present disclosure will be described in detail with reference to the drawings.

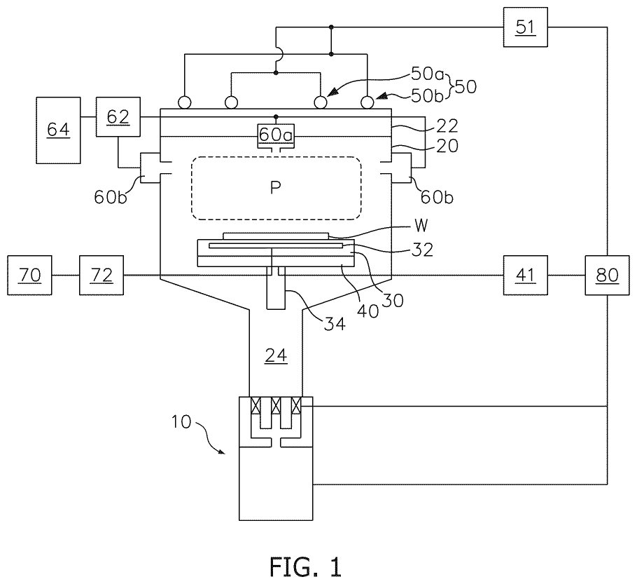

FIG. 1 is a diagram illustrating a substrate processing apparatus according to one or more embodiments.

Referring to FIG. 1, the substrate processing apparatus according to one or more embodiments may include a vacuum pump 10, a chamber 20, a stage 30, a lower electrode 40, a bias power supply 41, an upper electrode 50, a plasma power supply 51, a gas supply assembly, and a controller 80.

In one or more embodiments, the substrate processing apparatus may be an apparatus for etching a layer for etching on a substrate W disposed in the chamber 20 using an inductively coupled plasma (ICP). However, embodiments are not limited thereto. For example, the plasma generated by the substrate processing apparatus may be a capacitively coupled plasma or a microwave plasma. In addition, the substrate processing apparatus is not necessarily limited to an etching device, and for example, may be used as a deposition device, a cleaning device, etc. The substrate W provided to the substrate processing apparatus may include a semiconductor substrate, a glass substrate, etc.

The chamber 20 may provide a sealed space for performing a plasma etching process on the substrate W. The chamber 20 may be a cylindrical vacuum chamber. The chamber 20 may include a metal such as aluminum or stainless steel.

A stage 30 for supporting the substrate W may be disposed inside the chamber 20. The stage 30 may accommodate the substrate W. The stage 30 may include an electrostatic chuck for adsorbing the substrate W thereon with an electrostatic adsorption power. The electrostatic chuck of the stage 30 may adsorb the substrate W with electrostatic power by the DC voltage supplied from a power source 70 and prevent the substrate W from moving while the etching process is performed in the chamber.

In addition, the stage 30 may include a disc-shaped lower electrode 40 under the electrostatic chuck. The stage 30 may be coupled to a driver 34. The driver 34 may move vertically. That is, the lower electrode 40 may be moved vertically by the driver 34.

The substrate W may be accommodated on an upper surface of the stage 30, and a focus ring may be disposed around the substrate W. The diameter of the lower electrode 40 may be greater than the diameter of the substrate W. The lower electrode 40 may include, disposed therein, a cooling circulation channel for cooling. In addition, for the precision of the etching process, a cooling gas such as He gas may be supplied on the substrate W.

A port for loading and unloading the substrate W may be formed in a sidewall of the chamber 20. The substrate W may be loaded onto and unloaded from the stage 30 through the port.

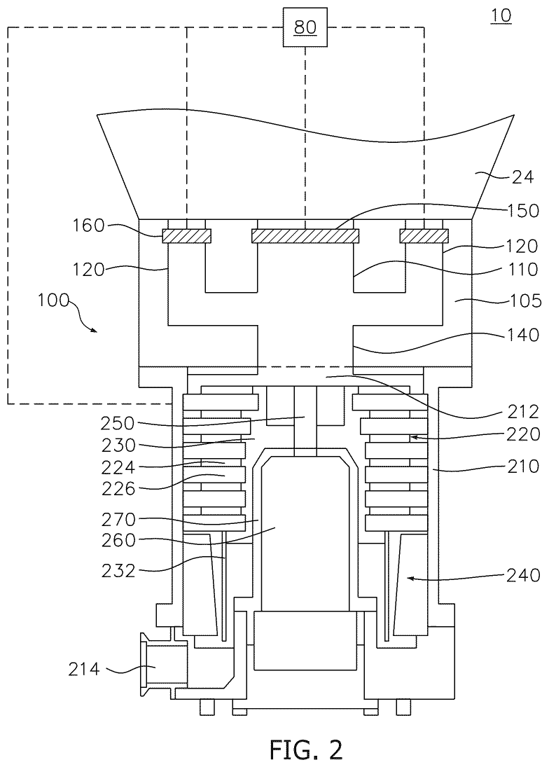

The chamber 20 may include an exhaust port 24 connected to the vacuum pump 10. The exhaust port 24 may be formed under the chamber 20. The vacuum pump 10 may be coupled to the exhaust port 24. The vacuum pump 10 may provide negative pressure into the chamber 20. For example, the vacuum pump 10 may be a turbo molecular pump (TMP). However, embodiments are not limited thereto. The vacuum pump 10 may include a pump and a pipe assembly. The pump may provide sound pressure to the space inside the chamber 20 through the pipe assembly. The structure of the vacuum pump 10 will be described in detail with reference to FIGS. 2 to 4.

The controller 80 may control the operation of the vacuum pump 10. For example, the controller 80 may control the pump of the vacuum pump 10 to adjust the space inside the chamber 20 to a desired vacuum pressure. In addition, the controller 80 may control the pipe assembly to control a flow path from the pump to the chamber 20 and a flow rate of the gas supplied to the chamber 20.

A cover 22 covering the chamber 20 may be formed on an upper portion of the chamber 20. The cover 22 may seal the upper portion of the chamber 20. The upper electrode 50 may be disposed on an outer upper portion of the chamber 20 to face the lower electrode 40. The upper electrode 50 may be disposed on the cover 22. The upper electrode 50 may include a high frequency antenna. The antenna may have a planar coil shape. The cover 22 may include a disc-shaped dielectric window. The dielectric window may include a dielectric material. For example, the dielectric window may include aluminum oxide (Al₂O₃). The dielectric window may transfer power from the antenna to the inside of the chamber 20.

For example, the upper electrode 50 may include an inner coil 50a and an outer coil 50b. The inner coil 50a and the outer coil 50b may have a spiral shape or a concentric shape. The inner coil 50a and the outer coil 50b may generate inductively coupled plasma in a plasma space P of the chamber 20. Although two coils have been described as an example, it will be understood that the number, arrangement, etc. of the coils are not limited thereto.

In one or more embodiments, the gas supply assembly may include gas supply pipes 60a and 60b, a flow controller 62, and a gas supply source 64. The gas supply pipes 60a and 60b may supply gases into the chamber 20. For example, the gas supply pipes may include a vertical gas supply pipe 60a penetrating the cover 22 and a horizontal gas supply pipe 60b penetrating the side of the chamber 20. The vertical gas supply pipe 60a and the horizontal gas supply pipe 60b may directly supply various gases into the plasma space P in the chamber 20.

The gas supply assembly may supply different gases at a desired ratio. The gas supply source 64 may store a plurality of gases, and the gases may be supplied through a plurality of gas lines respectively connected to the gas supply pipes 60a and 60b.

The flow controller 62 may control the supply flow rate of gases flowing into the chamber 20 through the gas supply pipes 60a and 60b. The flow controller 62 may independently or commonly control the supply flow rates of gases supplied to the vertical gas supply pipe 60a and the horizontal gas supply pipe 60b, respectively. For example, the gas supply source 64 may include a plurality of gas tanks, and the flow controller 62 may include a plurality of mass flow controllers (MFC) corresponding to each of the above gas tanks. The MFCs may independently control the supply flow rates of the gases.

In one or more embodiments, the plasma power supply 51 may apply plasma source power to the upper electrode 50. The plasma power supply 51 may apply sinusoidal power to the upper electrode 50 to form plasma in the chamber 20. The bias power supply 41 may apply bias source power to the lower electrode 40. The bias power supply 41 may apply non-sinusoidal power to the lower electrode 40.

The controller 80 may be connected to the plasma power supply 51 and the bias power supply 41 to control operations thereof. The controller 80 may include a microcomputer and various interfaces, and may control the operation of the plasma processing device according to programs and instructions stored in an external or internal memory.

The plasma power supply 51 may include a source RF power source and a source RF matcher. The source RF power source may generate a high frequency signal. The source RF matcher may match the impedances of the RF signal generated from the source RF power source to control plasma to be generated using the coils 50a and 50b.

The plasma power supply 51 may apply a high frequency power signal to the upper electrode 50 according to the plasma power control signal from the controller 80. For example, the high frequency power may be generated with RF power having a frequency range of about 13 MHz to about 2.45 GHz and a power range of about 100 W to about 1000 W.

When high-frequency power having a predetermined frequency (e.g., 13.56 MHz) is applied to the upper electrode 50, an electromagnetic field induced by the upper electrode 50 may be applied to the source gas injected into the chamber 20 to generate plasma.

The bias power supply 41 may apply a bias power signal to the lower electrode 40 according to a bias power control signal from the controller 80. The bias power supply 41 may include any circuits for generating a pulse signal having a non-sinusoidal voltage waveform and supplying a compensation current. In addition, the power supply 41 may apply bias power having a specific non-sinusoidal voltage waveform to the lower electrode 40.

The substrate processing apparatus may include a temperature controller of the stage 30. The temperature controller may include a heater and/or a cooler. For example, the temperature controller may include a heater 32 disposed inside the stage 30 to adjust the temperature of the stage 30, a power source 70 to supply power to the heater 32, and a filter 72 disposed between the heater 32 and the power source 70.

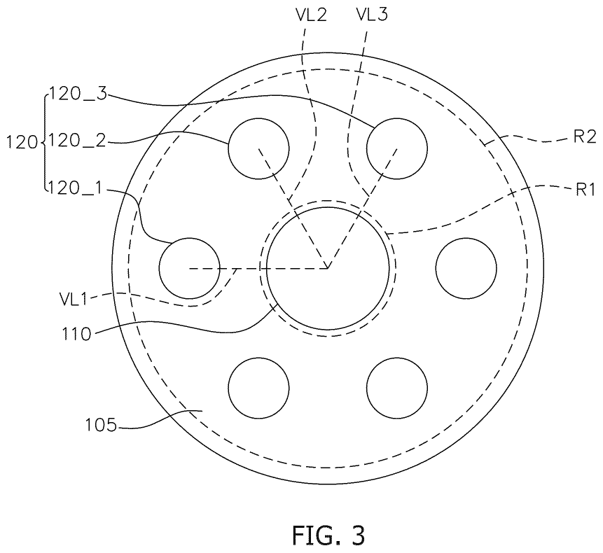

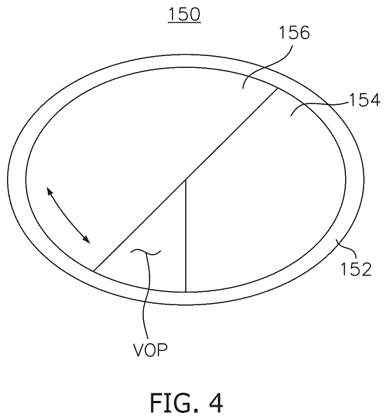

FIG. 2 is a diagram illustrating a vacuum pump according to one or more embodiments. FIG. 3 is a plan view illustrating a pipe assembly of a vacuum pump according to one or more embodiments. FIG. 4 is a diagram illustrating a valve of a vacuum pump according to one or more embodiments.

Referring to FIGS. 2 to 4, the vacuum pump 10 may include a pipe assembly 100, a housing 210, a pump 220, a screw groove portion 240, a high frequency motor 260, etc.

The pipe assembly 100 may be coupled to the housing 210. For example, a lower portion of the pipe assembly 100 may be coupled to a flange that is formed on an upper portion of the housing 210. The upper portion of the pipe assembly 100 may be coupled to the exhaust port 24. For example, the exhaust port 24 may be the exhaust port 24 of the substrate processing apparatus described in FIG. 1. The pipe assembly 100 may be a passage of gas moving from the exhaust port 24 to the housing 210.

The pipe assembly 100 may include a body 105, a first pipe 110, a plurality of second pipes 120, a common pipe 140, a first valve 150, and a plurality of second valves 160.

The first pipe 110 may be disposed in the body 105. A first end of the first pipe 110 may be connected to the chamber 20 through the exhaust port 24. That is, the first end of the first pipe 110 may penetrate an upper surface of the body 105. The second end of the first pipe 110 may be connected to the common pipe 140.

The plurality of second pipes 120 may be disposed in the body 105. The plurality of second pipes 120 may be disposed around the first pipe 110. A first end of each of the plurality of second pipes 120 may be connected to the chamber 20 through the exhaust port 24. That is, the first end of each of the plurality of second pipes 120 may penetrate the upper surface of the body 105. The second end of each of the plurality of second pipes 120 may be connected to the common pipe 140.

A first end of the common pipe 140 may be connected to an intake port 212 of the housing 210. A second end of the common pipe 140 may be connected to the first pipe 110 and all of the plurality of second pipes 120. That is, the gas suctioned through the first pipe 110 and the plurality of second pipes 120 may flow through the common pipe 140 to the intake port 212.

The body 105 may include a first region R1 and a second region R2. As illustrated in FIG. 3, in a plan view, the first region R1 may be located at the center of the upper surface of the body 105. The second region R2 may be disposed around the first region R1. The second region R2 may surround the first region R1.

In one or more embodiments, the first end of the first pipe 110 may be disposed on the first region R1. The first end of each of the plurality of second pipes 120 may be disposed on the second region R2. That is, the first ends of the plurality of second pipes 120 may be disposed around the first pipe 110.

The first ends of the plurality of second pipes 120 may be uniformly aligned around the first end of the first pipe 110. For example, the first ends of the second pipes 120 may be spaced apart around the first end of the first pipe 110 at a predefined angle.

Specifically, the plurality of second pipes 120 may include a first sub-pipe 120_1, a second sub-pipe 120_2, and a third sub-pipe 120_3. The first sub-pipe 120_1 may be adjacent to the second sub-pipe 120_2 in a clockwise direction. The second sub-pipe 120_2 may be adjacent to the third sub-pipe 120_3 in the clockwise direction.

A first virtual line VL1 may be formed by a first end of the first sub-pipe 120_1 and the first end of the first pipe 110. A second virtual line VL2 may be formed by a first end of the second sub-pipe 120_2 and the first end of the first pipe 110. A third virtual line VL3 may be formed by a first end of the third sub-pipe 120_3 and the first end of the first pipe 110. An angle between the first virtual line VL1 and the second virtual line VL2 may be the same as an angle between the second virtual line VL2 and the third virtual line VL3. The first to third virtual lines VL1, VL2, and VL3 may be virtual straight lines set based on the center of the first end of each of the pipes. That is, the virtual lines VL1, VL2 and VL3, for example, may be formed from a center of the first pipe 110 and respective centers of the sub-pipes 120_1, 120_2, and 120_3. For example, as illustrated in FIG. 3, if there are six second pipes 120, the angle between the first virtual line VL1 and the second virtual line VL2 may be 60 degrees.

In one or more embodiments, the length of the first virtual line VL1, the length of the second virtual line VL2, and the length of the third virtual line VL3 may be the same. In other words, the distance from the first end of the first pipe 110 to the first end of the first sub-pipe 120_1 may be the same as the distance from the first end of the first pipe 110 to the first end of the second sub-pipe 120_2. The distance may be a length set based on the center of first end of each of the pipes.

In one or more embodiments, the diameter of the first end of the first pipe 110 may be larger than the diameter of the first ends of the plurality of second pipes 120. However, embodiments are not limited thereto. For example, the diameter of the first end of the first pipe 110 may be equal to or smaller than the diameter of the first ends of the plurality of second pipes 120. Furthermore, the diameters may vary, such that some of the diameters of the first ends of the plurality of second pipes 120 may be greater than, equal to, or less than the diameter of the first end of the first pipe 110.

Although it is illustrated herein the first end of the first pipe 110 and the first ends of the plurality of second pipes 120 are circular, embodiments are not limited thereto. For example, the first end of the first pipe 110 and the first ends of the plurality of second pipes 120 may have a polygonal shape or various shapes including a plurality of curves.

The first valve 150 may be disposed on the first pipe 110. The first valve 150 may be disposed between the first end and the second end of the first pipe 110. The first valve 150 may adjust an amount of gas flowing into the first pipe 110. For example, the controller 80 may control a degree of opening and closing of the first valve 150 to adjust the amount of gas flowing into the first pipe 110.

The plurality of second valves 160 may be respectively disposed on the plurality of second pipes 120. The plurality of second valves 160 may be respectively disposed between the first ends and the second ends of the plurality of second pipes 120. The plurality of second valves 160 may adjust the amount of gas flowing into the plurality of second pipes 120, respectively. For example, the controller 80 may control the degree of opening and closing of each of the plurality of second valves 160 to adjust the amount of gas flowing into each of the plurality of second pipes 120 per unit time.

In FIGS. 2 and 3, it is illustrated that one first pipe 110 is provided, but the number of first pipes is not limited thereto. For example, a plurality of first pipes 110 may be provided. In this case, a plurality of first valves 150 may be disposed corresponding to each of the plurality of first pipes 110.

Referring to FIG. 4, the first valve 150 may include a valve body 152, a fixed plate 154, and a rotating plate 156. The valve body 152 may be coupled to the first pipe 110. The fixed plate 154 may be fixed to the valve body 152. The rotating plate 156 may be coupled to the valve body 152 and may rotate clockwise or counterclockwise on the fixed plate 154.

As the rotating plate 156 is rotated, size of an opening VOP between the rotating plate 156 and the fixed plate 154 may be adjusted. The controller 80 may control the degree of rotation of the rotating plate 156 of the first valve 150. That is, the controller 80 may adjust the flow rate of the gas flowing into the first pipe 110 by adjusting the size of the opening VOP of the first valve 150.

For convenience of description, the second pipe 120 and the second valve 160 may be described singularly, but the description may be applied to each of the plurality of second pipes 120 and each of the plurality of second valves 160. Each of the second valves 160 may be different from the first valve 150 only in size, and may have the same configuration and operation.

In one or more embodiments, the first end of the first pipe 110 and the first end of the second pipe 120 may be directly connected to the chamber 20. Throughout the description, when it is described that the first ends of the pipes 110 and 120 are directly connected to the chamber 20, it may refer to the pipes 110 and 120 that are passing through the valves 150 and 160 are connected only to the chamber 20. For example, the flow path from the first pipe 110 to the chamber 20 via the first valve 150 may not be connected to the flow path from the second pipe 120 to the chamber 20 via the second valve 160. In other words, the pipes 110 and 120 passing through the valves 150 and 160 may not be connected to each other through separate pipes. As a result, the first pipe 110 may be independently controlled by the first valve 150, and the second pipe 120 may be independently controlled by the second valve 160.

The controller 80 may individually control each of the first valve 150 and a plurality of second valves 160. In other words, the controller 80 may individually control the opening and closing of the valves associated with the first pipe 110, thereby opening and closing the first pipe 110, and the opening and closing of each of the valves associated with the second pipes 120, thereby opening and closing the second pipes 120. Thus, the controller 80 may control each valve to independently control the amount of gas flowing into the pipe that passes through each valve. For example, the controller 80 may adjust the degree of opening and closing of a second valve 160 selected from among the plurality of second valves 160. According to the adjusted degree of opening and closing of the second valve 160, the flow rate and flow path of the gas flowing from the chamber 20 through the pipes 110 and 120 to the intake port 212 may be controlled.

The housing 210 may include the intake port 212 and an exhaust port 214. The intake port 212 of the housing 210 may be connected to the common pipe 140 of the pipe assembly 100. The pump 220 and the screw groove portion 240 may be disposed between the intake port 212 and the exhaust port 214.

The pump 220 may be disposed in the housing 210. The pump 220 may include a rotor 230 coupled to a rotating shaft 250, a plurality of rotating blades 224 formed on an outer circumferential surface of the rotor 230, and a fixed blade 226 formed on an inner circumferential surface of the housing 210. The pump 220 may rotate the plurality of rotating blades 224 to form an airflow moving from the intake port 212 to the exhaust port 214.

The screw groove portion 240 may be formed under the pump 220. The screw groove portion 240 may include a stage fixedly coupled to the housing 210 and a screw groove formed on the stage. The screw groove may face the cylindrical rotor 232 formed under the rotor 230. An exhaust passage may be formed between the screw groove and the cylindrical rotor 232. The exhaust passage may be connected to the exhaust port 214.

The rotating shaft 250 may extend in a direction perpendicular to the same plane as the intake port 212. For example, the rotating shaft 250 may extend in a direction perpendicular to the ground. The rotating shaft 250 may be coupled to the high frequency motor 260. The high frequency motor 260 may be disposed in the motor housing 270. Although not illustrated, a protective bearing may be formed on the rotating shaft.

The gas introduced from the pipe assembly 100 and the intake port 212 by the driving of the high frequency motor 260 may be applied with downward momentum due to the action of the rotating blades 224 and the fixed blade 226 of the pump 220. In addition, the gas moves downstream while being compressed according to the high-speed rotation of the rotating blades 224. The compressed moving gas may flow along the exhaust passage and be discharged to the outside of the exhaust port 214.

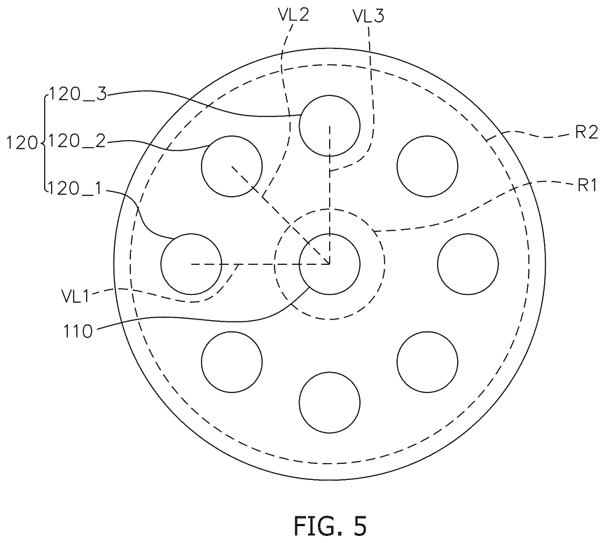

FIG. 5 is a diagram illustrating a substrate processing apparatus according to one or more embodiments. Description of aspects the same as or similar to those described above may be omitted.

Referring to FIG. 5, in the substrate processing apparatus according to one or more embodiments, the first ends of the plurality of second pipes 120 may be uniformly aligned around the first end of the first pipe 110. For example, the first ends of the second pipes 120 may be spaced apart around the first end of the first pipe 110 at a predefined angle.

Specifically, the plurality of second pipes 120 may include the first sub-pipe 120_1, the second sub-pipe 120_2, and the third sub-pipe 120_3. The first sub-pipe 120_1 may be adjacent to the second sub-pipe 120_2 in the clockwise direction. The second sub-pipe 120_2 may be adjacent to the third sub-pipe 120_3 in the clockwise direction.

A first virtual line VL1 may be formed by the first end of the first sub-pipe 120_1 and the first end of the first pipe 110. A second virtual line VL2 may be formed by the first end of the second sub-pipe 120_2 and the first end of the first pipe 110. A third virtual line VL3 may be formed by the first end of the third sub-pipe 120_3 and the first end of the first pipe 110. An angle between the first virtual line VL1 and the second virtual line VL2 may be the same as an angle between the second virtual line VL2 and the third virtual line VL3. The first to third virtual lines VL1, VL2, and VL3 may be virtual straight lines set based on the center of the first end of each of the pipes. That is, the virtual lines VL1, VL2 and VL3, for example, may be formed from a center of the first pipe 110 and respective centers of the sub-pipes 120_1, 120_2, and 120_3. For example, as illustrated, if there are eight second pipes 120, the angle between the first virtual line VL1 and the second virtual line VL2 may be 45 degrees.

The increased number of second pipes 120 (as compared to FIG. 3 for example) may facilitate the process uniformity control of the substrate processing apparatus. Although it is illustrated that the number of second pipes 120 is eight, embodiments are not limited thereto. For example, the number of second pipes 120 may vary, such as 10, 12, etc., depending on design.

In one or more embodiments, the diameter of the first end of the first pipe 110 may be the same as the diameter of the first end of the second pipes 120. That is, the size of the first end of the first pipe 110 may be the same as the size of the first ends of the second pipes 120.

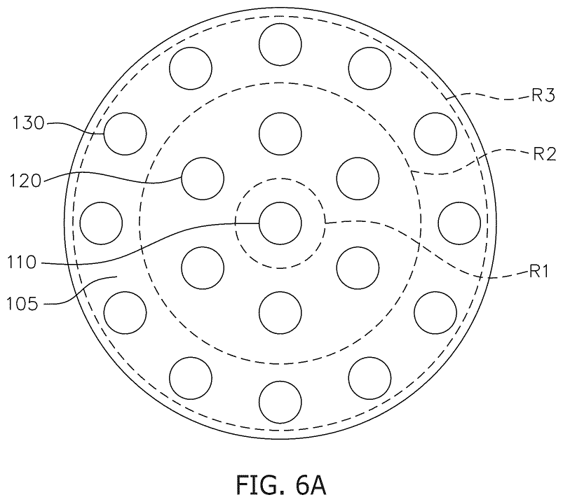

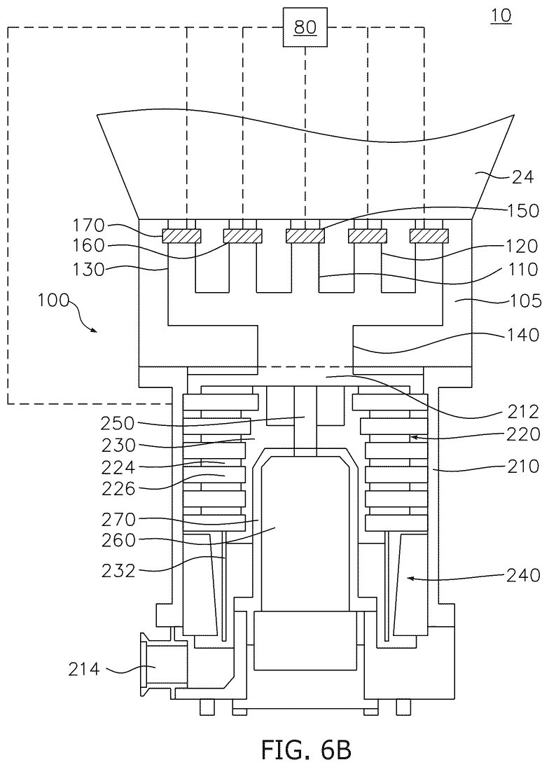

FIGS. 6A and 6B are diagrams illustrating a substrate processing apparatus according to one or more embodiments. Description of aspects the same as or similar to those described above may be omitted.

Referring to FIGS. 6A and 6B, in the substrate processing apparatus according to one or more embodiments, the body 105 may include the first region R1, the second region R2, and a third region R3. In a plan view, the first region R1 may be located at the center of the upper surface of the body 105. The second region R2 may be disposed around the first region R1. The third region R3 may be disposed around the second region R2. That is, the first region R1, the second region R2, and the third region R3 may be sequentially disposed with respect to the center of the upper surface of the body 105.

In one or more embodiments, the pipe assembly may further include a plurality of third pipes 130 and a plurality of third valves 170. The first end of the first pipe 110 may be disposed on the first region R1. The first end of each of the plurality of second pipes 120 may be disposed on the second region R2. The first end of each of the plurality of third pipes 130 may be disposed on the third region R3.

The second end of each of the plurality of third pipes 130 may be connected to the common pipe 140. That is, the second end of the first pipe 110, the second ends of the plurality of second pipes 120, and the second ends of the plurality of third pipes 130 may all be connected to the common pipe 140.

The plurality of third valves 170 may be coupled on the plurality of corresponding third pipes 130, respectively. The third valves 170 may be disposed between the first end and the second end of the third pipes 130, respectively. The third valves 170 may adjust the amount of gas flowing into the third pipes 130. For example, the controller may control the degree of opening and closing of each of the third valves 170 to adjust the amount of gas flowing into each of the third pipes 130.

In one or more embodiments, the number of third pipes 130 may be greater than the number of second pipes 120. However, embodiments are not limited thereto. Although it is illustrated that the sizes of the first end of the first pipe 110, the first end of the second pipe 120, and the first end of the third pipes 130 are the same, embodiments are not limited thereto.

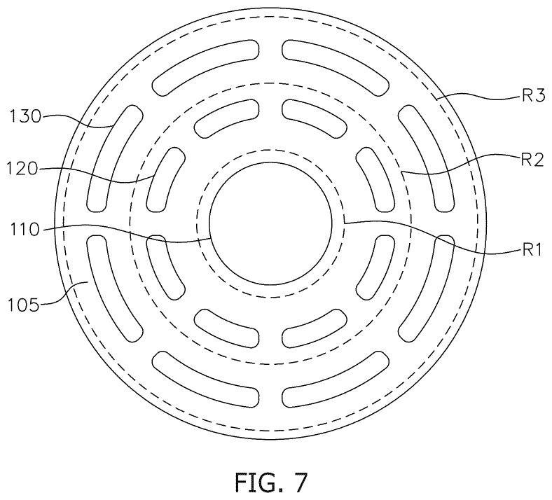

FIG. 7 is a diagram illustrating a substrate processing apparatus according to one or more embodiments. Description of aspects the same as or similar to those described above may be omitted.

Referring to FIG. 7, in the substrate processing apparatus according to one or more embodiments, the body 105 may include the first region R1, the second region R2, and a third region R3. In a plan view, the first region R1 may be located at the center of the upper surface of the body 105. The second region R2 may be disposed around the first region R1. The third region R3 may be disposed around the second region R2. That is, the first region R1, the second region R2, and the third region R3 may be sequentially disposed with respect to the center of the upper surface of the body 105.

The pipe assembly may further include the plurality of third pipes 130 and the plurality of third valves (e.g., valves 170 of FIG. 6B). The first end of each of the plurality of third pipes 130 may be disposed on the third region R3. The second end of each of the plurality of third pipes 130 may be connected to the common pipe 140. The plurality of third valves may be coupled on the plurality of corresponding third pipes 130, respectively. The third valves may be disposed between the first end and the second end of the third pipes 130, respectively.

In one or more embodiments, the first ends of the second pipes 120 and the first ends of the third pipes 130 may be similar to a circular arc shape. The first ends of the plurality of second pipes 120 may be disposed on a virtual circle centering on the first end of the first pipe 110. The second pipes 120 may be disposed and spaced apart along the virtual circle. First ends of the plurality of third pipes 130 may be disposed on a virtual circle centering on the first end of the first pipe 110. The second pipes 120 may be disposed and spaced apart along the virtual circle. The diameter of the virtual circle on which the third pipes 130 are disposed may be larger than the diameter of the virtual circle on which the second pipes 120 are disposed.

In one or more embodiments, the size of the first end of the first pipe 110 may be larger than the size of the first ends of the second pipes 120 and the size of the first ends of the third pipes 130. The “size” as used herein may refer to a cross-sectional area of each pipe exposed on the body 105.

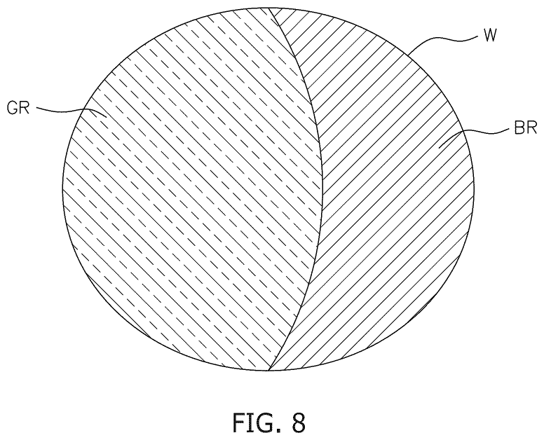

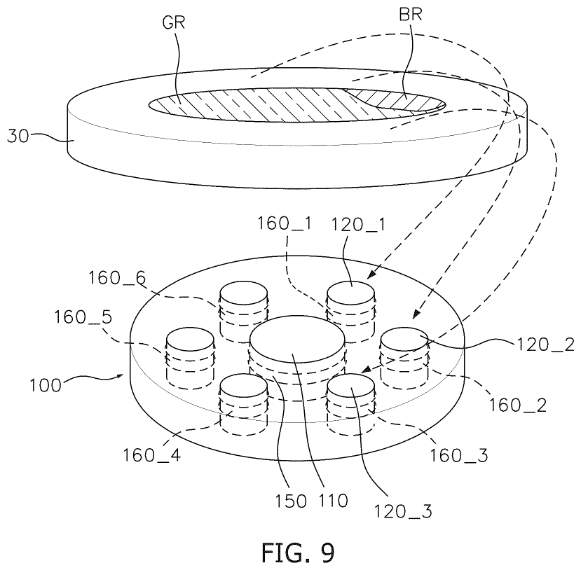

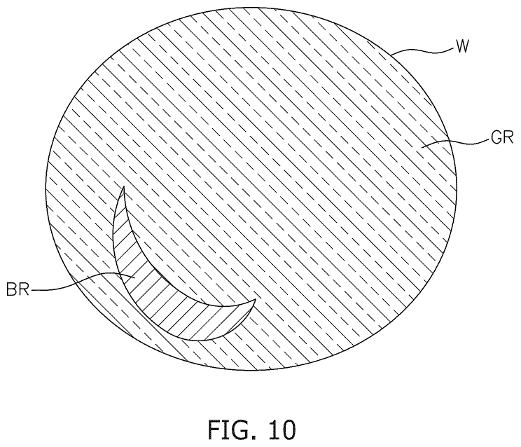

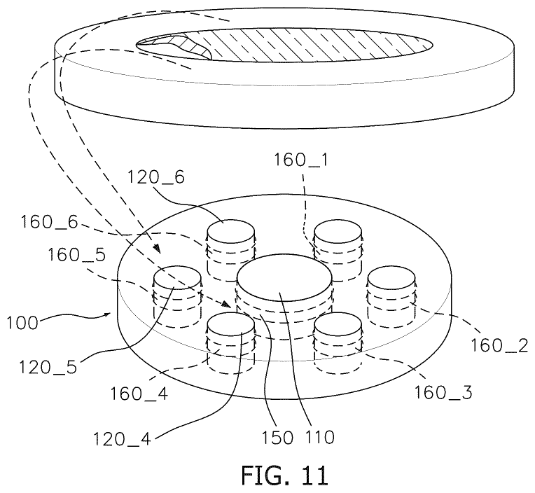

FIGS. 8 and 9 are diagrams illustrating a control method of a substrate processing apparatus according to one or more embodiments. FIGS. 10 and 11 are diagrams illustrating a control method of a substrate processing apparatus according to one or more embodiments. For convenience of description, configurations except the stage 30, the substrate W, and the pipe assembly 100 are omitted from the illustrations in FIGS. 9 and 11.

Referring to FIGS. 8 to 11 together with FIG. 1, with the control method of the substrate processing apparatus according to one or more embodiments, the substrate W including an object for etching may be provided in the substrate processing apparatus.

Uniformity data of the substrate W may be collected before the substrate W is provided to the substrate processing apparatus. The uniformity data may be, for example, a thickness of the object for etching formed on the substrate W, a critical dimension (CD), etc.

The substrate W may include a defective region BR and a non-defective region GR. The defective region BR and the non-defective region GR may be determined based on the uniformity data of the substrate W.

The controller 80 may receive the uniformity data of the substrate W. The controller 80 may determine a valve open/close value based on the received uniformity data and valve data. The valve data may be an open/close value of each of the first valve 150 and the plurality of second valves 160 set in the substrate processing apparatus (as well as the third valves 170 in one or more embodiments). The controller 80 may compare the received uniformity data with the valve data to determine the degree of opening and closing of the valves 150 and 160. In one or more embodiments, the open/close value may be expressed as an angle between the fixed plate 154 in FIG. 4 and the rotating plate 156 in FIG. 4 of the valve 150.

Specifically, the controller 80 may select a second valve 160 corresponding to the defective region BR from among the plurality of second valves 160. The controller 80 may determine the open/close value of the selected second valve 160 based on the uniformity data. In addition, the controller 80 may determine the open/close value of the remaining second valves 160, that is, the non-selected second valves 160 based on the uniformity data. Subsequently, the controller 80 may control the second valve 160 to reach the determined open/close value.

In one or more embodiments, the controller 80 may control the first valve 150 together while controlling the second valves 160. The controller 80 may adjust the degree of opening and closing of the first valve 150 according to the process recipe.

In FIGS. 8 and 9, the thickness of the object for etching disposed on the substrate W may not be constant. The object for etching disposed on the defective region BR may have a thickness greater than a target thickness range set in the previous process. The object for etching disposed on the non-defective region GR may have a thickness included in the target thickness range set in the previous process.

The controller 80 may adjust an etching amount of the defective region BR and the non-defective region GR. The controller 80 may control the second valves 160 so that more etching is performed on the defective region BR. For example, the size of the openings of the second pipes 120_1, 120_2 and 120_3 may be increased by increasing the open/close values of the second valves 160_1, 160_2, and 160_3 which are the second valves corresponding to the defective region B among the plurality of second valves 160. That is, the amount of gas suctioned into the second pipes 120_1, 120_2 and 120_3 connected to the second valves 160_1, 160_2, and 160_3 may increase. As a result, the etching amount of the object for etching disposed on the defective region BR may be greater than the etching amount of the object for etching disposed on the non-defective region GR, and the process uniformity of the object for etching disposed on the substrate W may be improved after the etching process.

Although it has been described that the amount of gas suctioned into the second pipes 120 and the etching amount of the object for etching corresponding to the second pipes 120 are proportional to each other, this may vary depending on the gas used in the etching process. For example, if a specific gas is used, the amount of gas suctioned into the second pipes 120 and the etching amount of the object for etching corresponding to the second pipes 120 may be inversely proportional.

In one or more embodiments, the open/close values of the second valves 160_1, 160_2, and 160_3 corresponding to the defective region BR may be different from each other. For example, the open/close value of the second valve 160_2 disposed at the rightmost side based on FIG. 9 may be different from the open/close values of the remaining second valves 160_1 and 160_3. That is, the controller 80 may individually control each of the plurality of second valves 160.

In FIGS. 10 and 11, the CDs of the object for etching disposed on the substrate W may be different. For example, an object for etching disposed on the defective region BR may have a smaller CD than a target CD range set in the previous process. The object for etching disposed on the non-defective region GR may have a CD included in the target CD range set in the previous process.

The controller 80 may adjust the etching amount of the defective region BR and the defective region GR. For example, the controller 80 may control the second valves 160 such that the open/close values of the second valves 160_4 and 160_5 (of second pipes 120_4 and 120_5) corresponding to the defective region BR are greater than the open/close values of the second valves 160_1, 160_2, 160_3, and 160_6 (of second pipes 120_1, 120_2, 120_3 and 120_6) corresponding to the non-defective region GR. As a result, the process uniformity may be improved by adjusting the etching amount of the object for etching disposed on the defective region BR and the object for etching disposed on the non-defective region GR. That is, the substrate processing apparatus according to one or more embodiments may individually control each of the first valve 150 and the plurality of second valves 160 to improve the process uniformity.

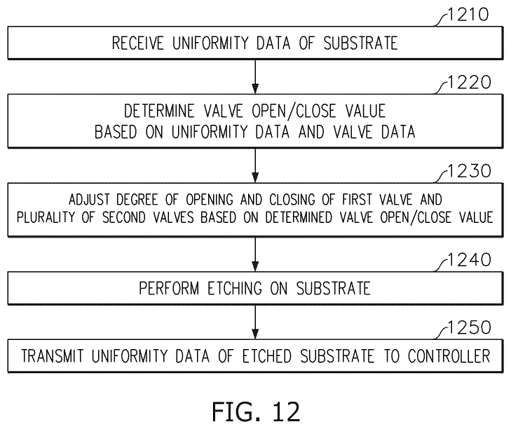

FIG. 12 is a flowchart illustrating a control method of a substrate processing apparatus according to one or more embodiments.

Referring to FIG. 12, with the control method of the substrate processing apparatus according to one or more embodiments, the controller of the substrate processing apparatus may receive the uniformity data of the substrate, in operation 1210. The controller may determine the valve open/close value based on the uniformity data and the valve data, in operation 1220. In one or more embodiments, determining the valve open/close value may include the controller setting a defective region of the substrate based on the uniformity data, selecting a second valve corresponding to the defective region, and determining the open/close value of the selected second valve. Furthermore, the controller may determine the open/close value of the non-selected second valves and the open/close value of the first valve.

The controller may adjust the degree of opening and closing of the first valve and the plurality of second valves based on the determined valve open/close values in operation 1230. The operation of adjusting the degree of opening and closing may include, while the first valve is open and all the second valves are closed, opening some second valves based on the determined valve open/close values. In one or more embodiments, the adjusting the degree of opening and closing may include, while the first valve and all of the plurality of second valves are open, closing some of the second valves based on the determined valve open/close values.

The etching process may be performed on the substrate in operation 1240. In one or more embodiments, the uniformity data of the etched substrate may be transmitted to the controller in operation 1250.

According to one or more embodiments, process uniformity may be improved by individually controlling each of a first value and a second valves associated with first pipes and second pipes. Furthermore, process uniformity may be improved by individually controlling the opening and closing of various pipes as described above.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A substrate processing apparatus, comprising:
a chamber;
a stage in the chamber and configured to accommodate a substrate;
a vacuum pump connected to the chamber and configured to provide negative pressure to the chamber; and
a controller,
wherein the vacuum pump comprises:
a pipe assembly connected to the chamber, the pipe assembly comprising a first pipe, at least one second pipe, a common pipe connected to the first pipe and the at least one second pipe, a first valve provided on the first pipe, and at least one second valve provided on the at least one second pipe;
an intake port connected to the pipe assembly; and
a pump connected to the intake port and configured to provide negative pressure,
wherein a first end of the first pipe and a first end of the at least one second pipe are connected to the chamber,
wherein a second end of the first pipe and a second end of the at least one second pipe are connected to the intake port through the common pipe, and
wherein the controller is configured to individually control opening and closing of the first valve and opening and closing of the at least one second valve.

2. The substrate processing apparatus according to claim 1, wherein the pipe assembly further comprises a body surrounding the first pipe and the at least one second pipe,
wherein the body comprises a center region and a second region surrounding the center region,
wherein the first end of the first pipe is provided on the center region, and
wherein the first end of the at least one second pipe is provided on the second region.

3. The substrate processing apparatus according to claim 2, wherein the body further comprises a third region surrounding the second region, and
wherein the pipe assembly further comprises a third pipe provided on the third region of the body, and a third valve.

4. The substrate processing apparatus according to claim 1, wherein the first valve is between the first end of the first pipe and the second end of the first pipe, and
wherein the at least one second valve is between the first end of the at least one second pipe and the second end of the at least one second pipe.

5. The substrate processing apparatus according to claim 1, wherein a diameter of the first end of the first pipe is larger than a diameter of the first end of the at least one second pipe.

6. The substrate processing apparatus according to claim 1, wherein the at least one second pipe comprises a plurality of second pipes, and
wherein the plurality of second pipes are spaced apart around the first pipe at a predetermined angle.

7. The substrate processing apparatus according to claim 1, wherein the at least one second pipe comprises a first sub-pipe and a second sub-pipe, and
wherein a distance from the first end of the first pipe to a first end of the first sub-pipe is the same as a distance from the first end of the first pipe to a first end of the second sub-pipe.

8. The substrate processing apparatus according to claim 1, wherein the first valve comprises a fixed plate and a rotating plate, and
wherein the rotating plate is configured to be rotated clockwise or counterclockwise on the fixed plate.

9. The substrate processing apparatus according to claim 1, further comprising an upper electrode in the chamber and configured to provide plasma.

10. The substrate processing apparatus according to claim 1, wherein the vacuum pump further comprises an exhaust port connected to the pump, and
wherein the pump is configured to produce an airflow that is suctioned from the intake port and discharged to the exhaust port by rotating a rotating blade.

11. A substrate processing apparatus, comprising:
a chamber;
a stage in the chamber and configured to accommodate a substrate;
an upper electrode in the chamber and configured to provide plasma on the stage;
a vacuum pump connected to the chamber and configured to provide negative pressure to the chamber; and
a controller,
wherein the vacuum pump comprises:
a pipe assembly connected to the chamber, the pipe assembly comprising a first pipe, a plurality of second pipes, a common pipe connected to the first pipe and the plurality of second pipes, a first valve provided on the first pipe, a plurality of second valves respectively provided on the plurality of second pipes, and a body surrounding the first pipe and the plurality of second pipes;
an intake port connected to the pipe assembly; and
a pump connected to the intake port and configured to provide negative pressure,
wherein the body comprises a center region and a second region around the center region, and
wherein a first end of the first pipe is provided on the center region of the body, and first ends of each of the plurality of second pipes are provided on the second region of the body.

12. The substrate processing apparatus according to claim 11, wherein the controller is configured to receive uniformity data of a substrate and control the first valve and each of the plurality of second valves based on the uniformity data.

13. The substrate processing apparatus according to claim 11, wherein the controller is configured to determine a defective region of the substrate based on uniformity data of the substrate, and control, among the plurality of second valves, a second valve corresponding to the defective region.

14. The substrate processing apparatus according to claim 11, wherein the first end of the first pipe and the first ends of each of the plurality of second pipes are directly connected to the chamber, and
wherein a second end of the first pipe and second ends of each of the plurality of second pipes are connected to the intake port through the common pipe.

15. The substrate processing apparatus according to claim 14, wherein the first valve is between the first end of the first pipe and the second end of the first pipe, and
wherein the plurality of second valves are respectively between the first ends and second ends of the plurality of second pipes.

16. A control method of a substrate processing apparatus, comprising:
receiving uniformity data of a substrate;
determining a valve open/close value based on the received uniformity data and valve data; and
adjusting a degree of opening and closing of a first valve and a plurality of second valves based on the determined valve open/close value,
wherein a first end of the first valve is provided in a central region of a pipe assembly, and first ends of each of the plurality of second valves are provided around the first valve.

17. The control method according to claim 16, wherein the determining the valve open/close value comprises:
setting a defective region of the substrate based on the uniformity data;
selecting a second valve among the plurality of second valves corresponding to the defective region; and
determining an open/close value of the selected second valve.

18. The control method according to claim 16, wherein the adjusting the degree of opening and closing comprises;
opening the first valve and closing all of the plurality of second valves; and
opening some of the plurality of second valves based on the determined valve open/close value.

19. The control method according to claim 16, wherein the adjusting the degree of opening and closing comprises;
opening the first valve and opening all of the plurality of second valves; and
closing some of the plurality of second valves based on the determined valve open/close value.

20. The control method according to claim 16, further comprising transmitting uniformity data of an etched substrate.
